(19) United States
(12) Patent Application Publication
(10) Pub. No.: US 2008/0191268 A1
(43) Pub. Date: Aug. 14, 2008

(54) INTEGRATED CIRCUIT AND METHOD OF MANUFACTURING AN INTEGRATED CIRCUIT

(75) Inventors: Franz Hofmann, Muenchen (DE); Michael Specht, Muenchen (DE); Josef Willer, Riemerling (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/674,809

(22) Filed: Feb. 14, 2007

(51) Int. Cl. H01L 29/788; H01L 21/336

(52) U.S. Cl. 257/324; 438/261; 257/E21.422; 257/E29.3

(57) ABSTRACT

An integrated circuit and method of manufacturing an integrated circuit is disclosed. In one embodiment, the integrated circuit includes a gate structure which includes a polysilicon double layer. The polysilicon double layer having a first polysilicon layer and a second polysilicon layer formed above the first polysilicon layer, the first polysilicon layer being doped with positive ions to a higher concentration than the second polysilicon layer.

### BACKGROUND

The present invention relates to an integrated circuit and to a method of manufacturing an integrated circuit.

Integrated circuits of semiconductor devices may include one or more layers having positively or negatively doped polysilicon. It can be of importance for the functionality of such a semiconductor device that the concentration of the dopant within the polysilicon layer corresponds to the respective preset target concentration as far as possible.

In some applications, it may also be necessary to have different degrees of doping within the polysilicon layer. In this case it may be desirable to place the doping ions as exact as possible into the desired region.

For these and other reasons, there is a need for the present invention.

### SUMMARY

One embodiment provides a method of manufacturing an integrated circuit. The method includes providing a first polysilicon layer as part of a gate structure above a semiconductor carrier; doping the first polysilicon layer with positive ions by a plasma ion doping; and depositing a second polysilicon layer above the first polysilicon layer and doping the second polysilicon layer with positive ions by an implantation process.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1 to 11 illustrate different processes of providing a semiconductor memory according to one embodiment of the present invention.

FIG. 12 illustrates respective cross sections of a memory cell area and of the periphery of the memory cell area in a SONOS memory device according to one embodiment the invention.

FIG. 13 illustrates a flow diagram of an example of a method according to one embodiment of the invention.

FIG. 14 illustrates a flow diagram of another example of a method according to a further embodiment of the invention.

FIG. 15 illustrates a system according to a further embodiment of the invention.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Embodiments of the invention will now be described with reference to the drawings. The embodiments in the drawings are given as an example only and are not intended to limit the scope of the invention. For example, the embodiment relating to SONOS cells is not to be seen as limiting as other embodiments not related to SONOS cells may easily be derived based on the below description without departing from the spirit of the invention.

Therefore, according to one embodiment, the integrated circuit is a SONOS-memory device. Of course, there are other embodiments, as for example other kinds of memory devices, or even other semiconductor devices.

A SONOS-memory constitutes one possible embodiment of an EEPROM which is an electrically erasable programmable read-only memory. SONOS memories may e.g., be used as low voltage, high density EEPROMs. A SONOS-memory has as a layer sequence an ONO (oxide-nitride-oxide) dielectric structure in the gate area of the memory. The structure of a SONOS-memory cell, as it is understood here, can also include modified layers, which means that additional elements or compounds are contained in the oxide layers and/or the nitride layer. In general, the ONO dielectric structure is one example of a charge trapping layer provided between insulating layers. On top of the ONO structure, there is deposited a polysilicon layer. Such a SONOS-memory device may have memory cells having a positively doped polysilicon layer (p⁺-poly-Si layer).

A SONOS memory device may be built up of several kinds of transistors. According to one embodiment, the memory cell transistors are n-channel transistors having a p⁺ poly-Si (poly silicon) layer. The transistors in the periphery area of the memory cells may include n-channel and p-channel transistors. Those periphery transistors have their poly-Si layers formed as n⁺ layers in the first case and either formed as p⁺ or n⁺ layers in the second case. The n⁺ layers in the second case are employed if so called “buried channel” PMOS devices are produced.

The doping of the poly-Si layers may be carried out either via insitu doping or by conventional techniques such as implantation of boron ions.

According to another embodiment, an integrated circuit and a method of manufacturing an integrated circuit may be provided. The integrated circuit may have a polysilicon double layer, the polysilicon double layer e.g., having a first polysilicon layer and a second polysilicon layer formed above the first polysilicon layer, the first polysilicon layer being doped with positive ions to a higher concentration than the second polysilicon layer.

Due to the fact that two polysilicon layers may be provided having positive ions, e.g., boron ions, therein, it is possible to have a high ion concentration on an underside, e.g., in a lower region, of the double polysilicon structure and a lower ion concentration in the upper polysilicon layer. The expression “underside” as it is meant here, is intended to designate that layer of the polysilicon double layer which is directed to or faces an underlying gate structure in the integrated circuit. In a further embodiment, the ions may be induced into the different polysilicon layers by different methods.

For example, a higher concentration of positive ions in the lower or first polysilicon layer may be of advantage in a memory cell area of a semiconductor memory, whereas in a periphery area of the memory cell, the boron concentration of the polysilicon layer may tolerated to be lower.

If an uppermost layer of an oxide-nitride-oxide layer structure (ONO layer) is doped with positive ions to a high extent, or even saturated with positive ions, the high concentration of positive ions in the lower polysilicon layer or first polysilicon layer may have the effect that no boron will be “sucked away” i.e., diffuse from the top oxide layer of the ONO-structure into the overlaying poly-Si layer. One embodiment of the present invention dopes the lower polysilicon layer with a desired high concentration.

On the other hand, a high concentration of positive ions in the polysilicon layer may not be desired in the memory cell periphery area. One embodiment of the present invention also allows a doping with a lower concentration in the memory cell periphery area and simultaneously having the desired high concentration of dopant within the lower polysilicon layer of the memory cell area.

According to one embodiment, the second or upper polysilicon layer has a lower concentration of boron ions, and therefore that upper polysilicon layer of the memory cell area can be produced simultaneously with the polysilicon layer of the periphery area of the memory cell. In other words, it is possible according to one embodiment that the memory cell area includes the double layer polysilicon structure, whereas the periphery area has only the second polysilicon layer thereon so that in that area, a lower concentration of positive ions in the poly-Si is achieved.

In reference to the drawings, the different layers may not be in scale due. Some layer thicknesses are exaggerated in order to increase the intelligibility of the illustrated process.

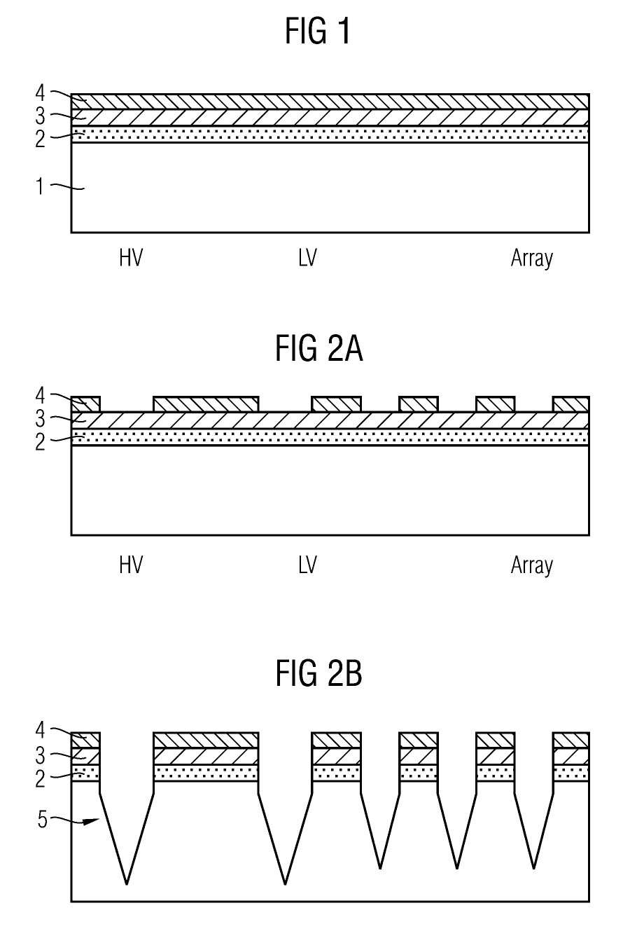

In FIG. 1, the production of starting layers for a SONOS memory device is illustrated. The starting layers constitute the basic layers onto which the further structure is to be built. As it can be understood from the following figures, the SONOS memory device has a plurality of regions which can be distinguished in cross section. In the figures, the different areas are denoted as “HV” which means high voltage area and refers to the voltage applied to that region in function, “LV” which means low voltage area, and “array” which means the area in which the memory cell transistors are provided and the remaining circuitry. The expression “array” is due to the well known fact that the corresponding transistors are grouped in arrays. The HV and LV areas constitute the periphery areas of the memory cell. In that periphery areas, dual work function CMOS transistors may be provided which have poly gate layers doped by implantation (n⁺ and p⁺ doping).

It is to be mentioned that the regions or areas illustrated in the drawings and described herein only constitute one example of different functional areas in an integrated circuit. Generally, the different areas may relate to areas in which different kinds of transistors are provided and to the remaining circuitry. The polysilicon layers may especially constitute a part of the gate structure of those transistors.

The deposition of the starting layers is substantially as in the state of the art. In FIG. 1, reference sign 1 denotes a semiconductor carrier, reference sign 2 is a pad oxide which is deposited with a layer thickness of about 8 nm. On the pad oxide, a first dummy polysilicon layer 3 is deposited which will be removed in further processes. As it is generally known, a dummy layer may e.g., be a layer that is used only at some stage of a manufacturing process, but is not part of the final product. Thereupon a nitride hard mask 4 is provided.

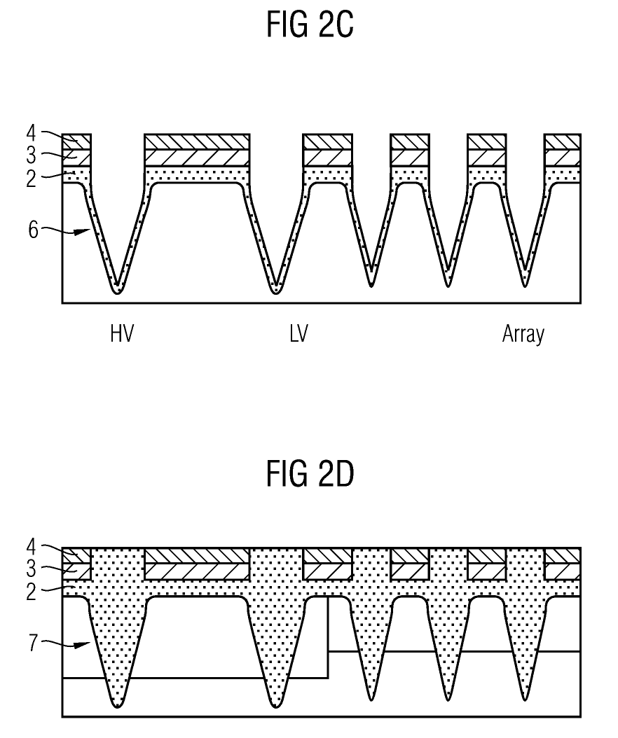

FIG. 2 illustrates a next production process of one embodiment of a SONOS memory device. In this process a shallow trench isolation (STI) is formed. The first mask 4 which in this case is a nitride hard mask, covers the memory cell array as well as the periphery area of that array. In FIG. 2a, reactive ion etching is carried out on the nitride hard mask 4 and on the polysilicon dummy layer 3. Next, as can be seen from FIG. 2b, a shallow trench etch takes place with the bottom part of the semiconductor carrier 1 being etched with a taper and the top part (pad oxide 2) being etched with vertical sidewalls. According to this Figure, the resulting shallow trenches 5 are of different shapes in the array area and in the periphery area (HV and LV).

As it is depicted in FIG. 2c, a sacrificial oxide layer 6 is formed on the sidewalls of the shallow trenches 5. In the periphery, the corners of the trenches are rounded, whereas in the gate cell array, fins are formed.

As it is illustrated in FIG. 2d, the shallow trenches are filled with an oxide, whereupon chemical mechanical polishing (CMP) of the oxide on an upper surface takes place.

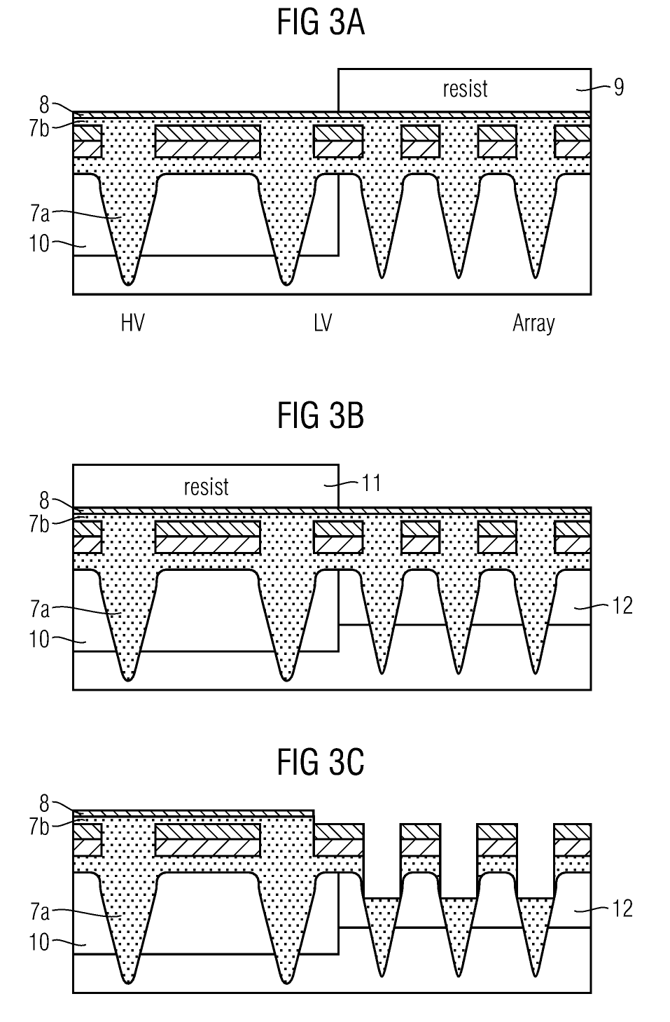

In FIG. 3, there is disclosed the process of formation of the well implants within the semiconductor memory to be formed. FIG. 3a illustrates that an additional oxide layer 7b is grown both in the periphery and in the array area and on that layer, a nitride hard mask 8 is deposited. Furthermore, a resist mask 9 is laid down in the array area so that well implants 10 can be provided in the area not covered by the resist mask.

Now, as illustrated in FIG. 3b, a resist mask 11 is placed upon the top surface of the periphery area and well implants 12 are provided in the array area. Furthermore, as can be seen from FIG. 3c, the nitride layer 4, the polysilicon layer 3 and the pad oxide layer 2 are etched, for example, by reactive ion etching which is known in the art. Afterwards, the resist mask 12 is stripped off and a recess is made in the oxide 7 of the shallow trench isolation.

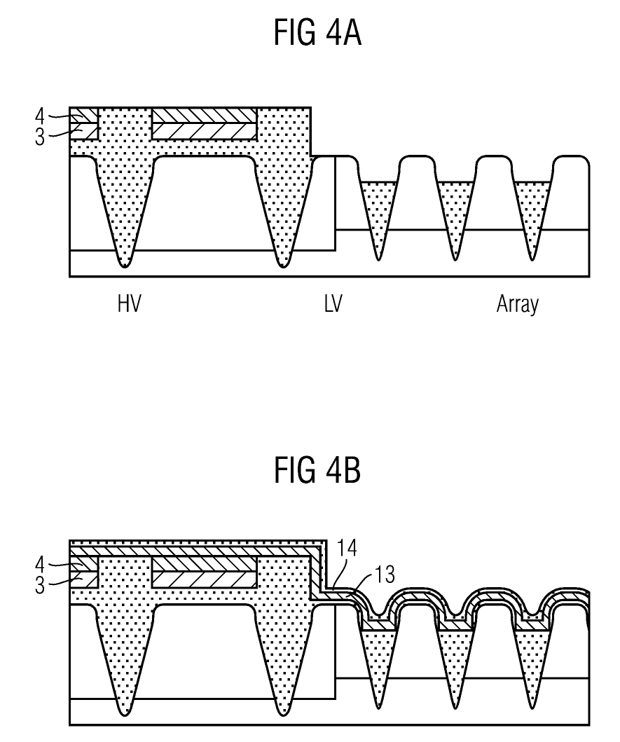

FIG. 4 depicts the formation of an ONO-structure in the gate array area. First, the upper nitride layer 4 is etched, by wet etching. Afterwards, the underlying dummy polysilicon layer 3 is also etched, by reactive ion etching. Also the pad oxide 2 is etched, here again by wet etching. In FIG. 4a a state is illustrated in which the aforementioned etching processes have already taken place. Afterwards, as it can be seen from FIG. 4B, a nitride layer 13 and an oxide layer 14 are grown on both, the periphery and the cell array area. In the cell array area, layers 13 and 14 constitute the upper layers of the ONO-structure while the oxide layer 7a which fills the shallow trenches in that area constitutes a bottom layer of the ONO-structure.

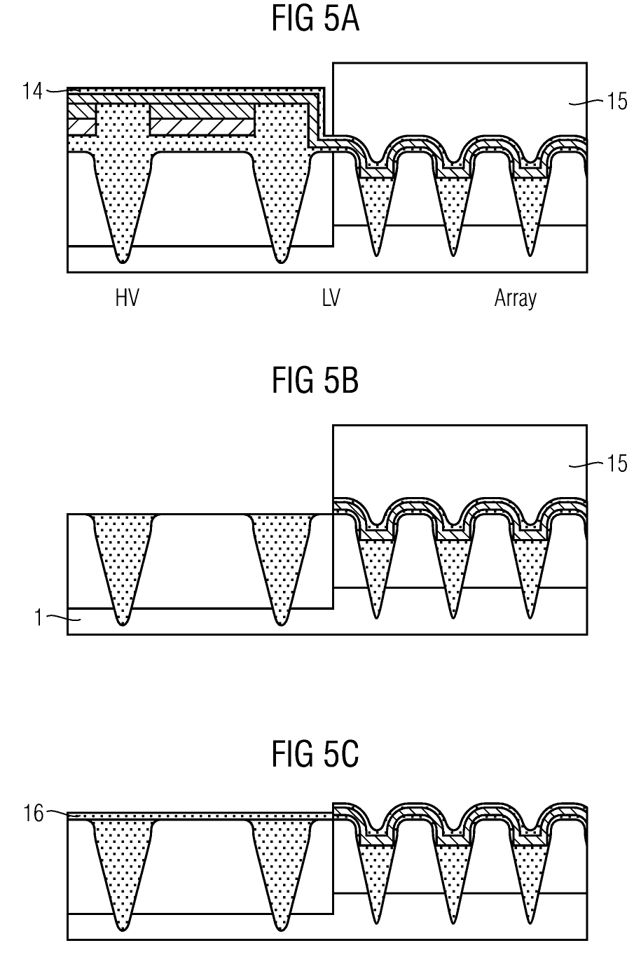

Turning now to FIG. 5, that Figure illustrates the processes of partial removal of the ONO-structure and growth of gate oxide at the area of select gates and in the LV area.

As it can be seen from FIG. 5a, a further resist mask 15 is deposited on the array area of the semiconductor memory device to be formed. Therefore, the etching processes described in the following will not affect the layers in that area.

Then, etching of the oxide 14 and nitride 13 layers, by reactive ion etching, is carried out. In this connection, the polysilicon layer 3 serves as an etch stop. Afterwards, the polysilicon layer 3 is etched by reactive ion etching. The pad oxide 2 is etched by wet etching in those areas which are not covered by the resist mask 15. The result of this process is depicted in FIG. 5b.

As it can be seen from FIG. 5C, the resist mask 15 is then stripped off and a gate oxide layer 16 is grown in the select gate area and in the LV/HV periphery.

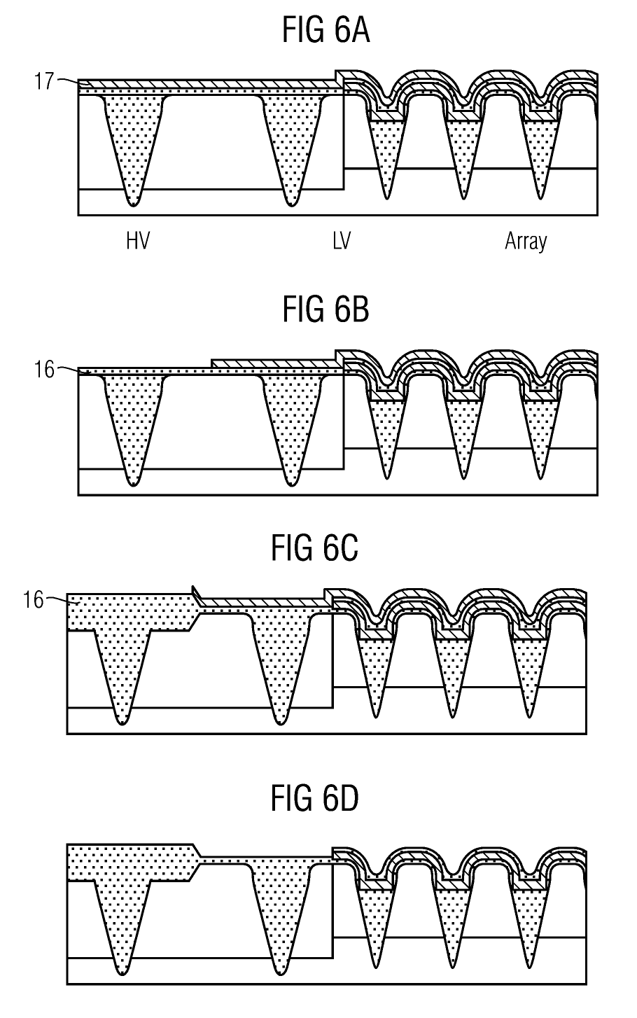

As to FIG. 6, this Figure illustrates generally the forming of the gate oxide in the HV periphery. A nitride hard mask 17 is deposited both in the periphery area and on the array area, as illustrated in FIG. 6a. Thereafter, reactive ion etching of the nitride takes place only in the HV region of the periphery area (FIG. 6b). Afterwards, the gate oxide layer 16 is wet etched to a certain depth, for example about 8 nm, in that area. Thereafter, as it can be seen from FIG. 6c, the oxide layer 16 is grown again in the HV area, to a thickness of about 35 nm and finally, as it can be seen from FIG. 6d, the nitride hard mask layer 17 is etched away, for example by wet etching.

Up to this point, the processes illustrated in the figures and described herein are directed to the manufacture of the base layers of a semiconductor memory, including a gate structure and its periphery. Other intermediate processes can be included to form certain structures as this will be understood by the person skilled in the art. At this point, there is the ONO layer structure as the upper layers in the memory cell area and the gate oxide layer 16 as the uppermost layer in the periphery area.

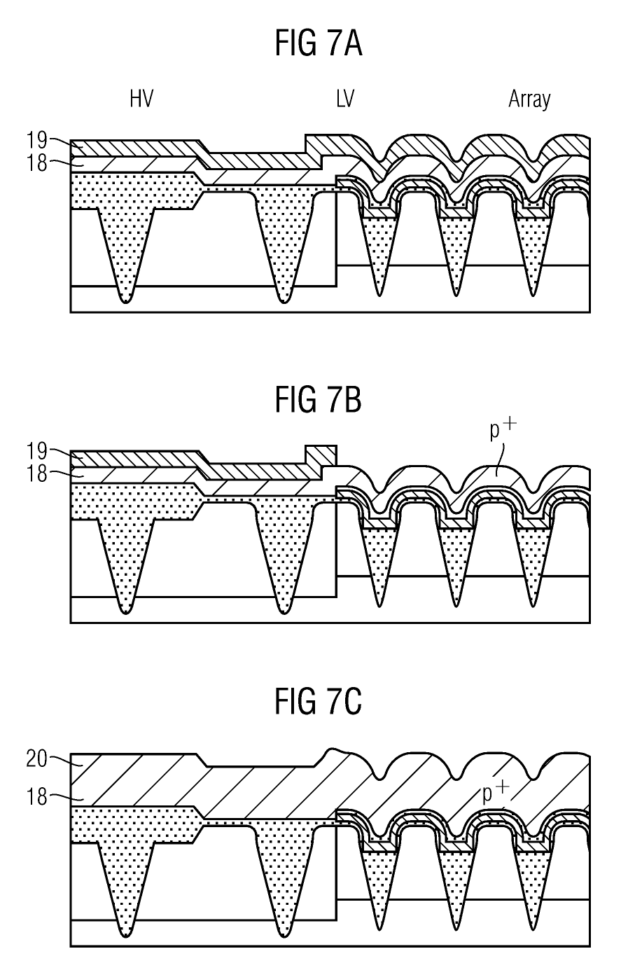

In reference to FIG. 7, this Figure illustrates the processes of depositing a poly-Si gate layer. In FIG. 7a, a first poly-Si gate layer 18 is grown in the periphery area and the array area. The first poly-Si gate layer 18 may have a thickness of about 15 to 25 nm, and in one embodiment about 20 nm. As will be understood by a person skilled in the art, the thickness may vary according to the parameters of the other layers and according to the intended use. Afterwards, a nitride hard mask 19 is deposited on top of first poly-Si layer 18, also in both areas. The nitride hard mask 19 which serves as an implant mask, is then removed in the array area so as to expose the underlying poly-Si.

FIG. 7b illustrates the state in which doping of the first poly-Si layer 18 takes place in the array area. Due to the fact that the periphery area is covered with the nitride hard mask 19, doping only takes place in the array area where the memory cell transistors of the memory device are to be formed. The first poly-Si gate layer 18 is doped by a plasma doping process. By this plasma doping process, positive ions, boron ions are induced into the first poly-Si gate layer 18 and also into the underlying top oxide layer 14 of the ONO-structure. By this means, a high concentration of ions can be achieved in both layers due to the fact that plasma doping has the advantage of a very shallow penetration depth.

The top oxide layer 14 if the ONO-structure is doped to an extent to be saturated with ions. Due to the fact that with plasma doping, a high concentration of ions can also be achieved in the first poly-Si gate layer 18, the danger of depletion of charge corridors due to a low concentration of ions, i.e. boron, at an interface of layers 14 and 18 during high temperature processes can be avoided. The ion concentration of the first poly-Si gate layer 18 should be about 10²¹ ions per cm³ or higher.

As illustrated in FIG. 7c), the nitride hard mask 19 is then removed from the periphery area. Then, a second poly-Si gate layer 20 is grown on the first poly-Si gate layer 18. The second poly-Si gate layer 20 is in one embodiment thicker than the first poly-Si gate layer 18 and is provided on both of the periphery area and the array area.

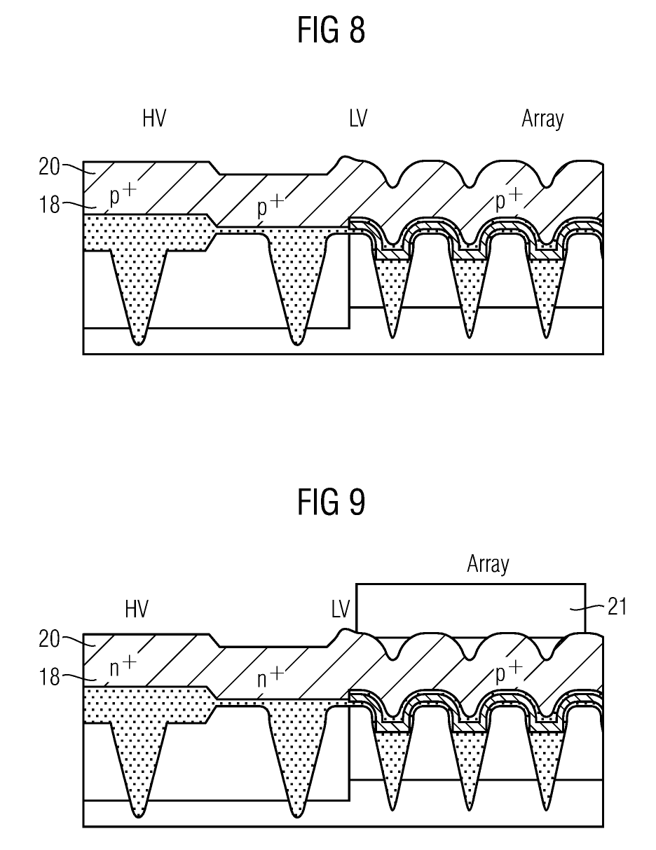

FIGS. 8 and 9 illustrate the processes of forming gate implants in the second poly-Si gate layer 20 in different regions. It is to be understood that although both figures are section views through a SONOS memory device, those sections have been made at different levels within the device.

FIG. 8 illustrates a section through a level of the memory device at which p-MOS transistors are to be formed in the periphery area. At this stage, the p⁺ gate implants in the upper or second poly-Si gate layer 20 are formed. In this case, doping, in one embodiment with boron ions, takes place by a process different from the plasma doping process used for the first poly-Si gate layer 18. Of course, in an alternative embodiment, it is also possible to use plasma doping at this stage.

Due to the fact that it is not necessary for the second poly-Si gate layer 20 to be doped to such a high extent as the first poly-Si gate layer 18, a conventional ion implantation process can be carried out. As this is known to the person skilled in the art, ion implantation can be carried out at room temperatures. The dopant atoms are accelerated to a high speed and thus shot into the poly-Si layer with high energies. In practice, energies of 5 keV to 50 keV are used. Such a process leads to a certain ion concentration gradient in the second poly-Si gate layer 20. Normally, by such a process, the concentration of ions is higher at the region at the surface of the second poly-Si gate layer 20 and decreases in the depth direction of that layer. This means that at the array area, the ion concentration decreases with increasing depth within the second poly-Si gate layer 20 and suddenly increases again at the interface with the first poly-Si gate layer 18 due to the fact that the latter has been doped to a concentration of at least about 10²¹ ions per cm³ in the preceding plasma doping process.

During the above described ion implantation at the array area and at a region of p-MOS transistors to be formed in the periphery area, a region of n-MOS transistors to be formed in the periphery area is covered with a resist mask (not illustrated in the drawings) in order to avoid p⁺ doping in that region.

As it has been mentioned above, FIG. 9 is a sectional view at another level in the thickness direction (direction perpendicular to the plane of the sheet) of the semiconductor memory device. In the process illustrated in FIG. 9, the array area (and also the p-MOS transistor region which is not illustrated in this figure) is covered with a resist mask 21 in order to avoid further doping of those areas. Then, n⁺ doping of the second poly-Si gate layer 20 in the regions of n-MOS transistors takes place. At last, the resist mask 21 is removed again.

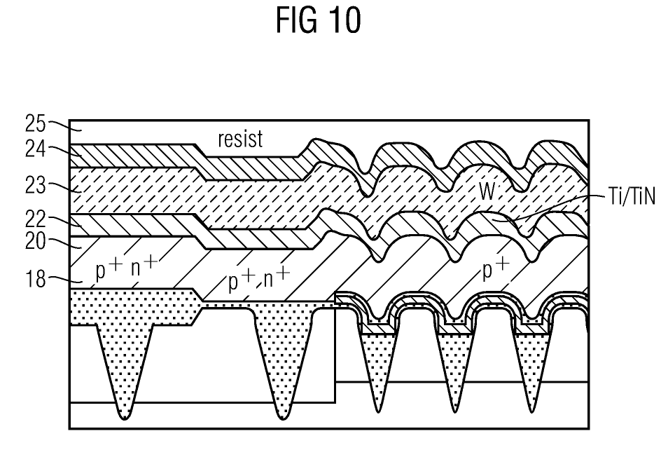

As a next process the result of which is illustrated in FIG. 10, a gate stack is formed on the second poly-Si gate layer 20. This process again is known in the art. A titanium/titanium nitride layer 22, a tungsten layer 23 for a word line, a hard mask nitride layer 24 and finally a resist layer 25 are deposited in the given order on the second poly-Si gate layer 20. The titanium/titanium nitride layer 22 serves as a diffusion barrier between the tungsten layer 23 and the second poly-Si layer 20 so that the formation of WSi is avoided. It has to be mentioned that the materials used and described herein, especially those of layers 22 and 23 are not mandatory. The person skilled in the art will know a range of materials suitable for fulfilling the purpose of those layers.

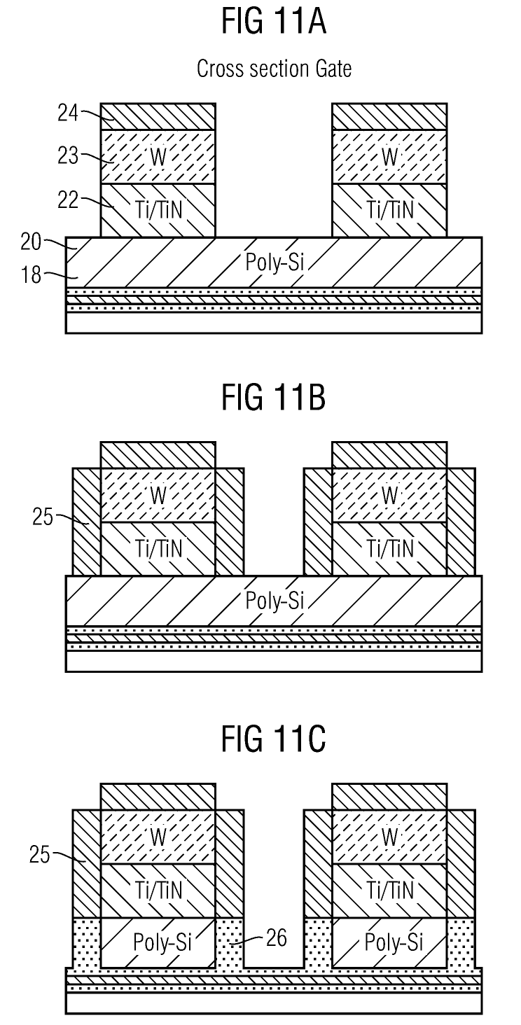

As a final process, the forming of gate lithography and the subsequent etching is carried out. That process is, according to this embodiment, the same in a gate region of the memory cell array area and in a gate region of the periphery area. For this reason, FIG. 11 illustrates only one cross section at a gate region. In a first sub-process the resist layer 25 is selectively etched away in a certain region. Then, in the same region, also the nitride hard mask layer 24, the tungsten layer 23 and the Ti/TiN layer 22 are etched away. The resulting stage is illustrated in FIG. 11a.

As can be seen from FIG. 11b, a further nitride layer 24 is deposited and etched away except from wall regions of the stacks from layers 22 and 23, so that a spacer layer is formed from the nitride layer 24. In this way, the remaining tungsten layers 23 in the stacks are completely encapsulated, so that a following high temperature treatment does not affect those layers.

Then, as it is illustrated in FIG. 11c, the second poly-Si gate layer 20 is etched away in the regions outside the stacks of layers 22 and 23. The second poly-Si gate layer 20 remaining within the stacks is re-oxidized at its side walls in order to provide an oxide spacer layer at that region.

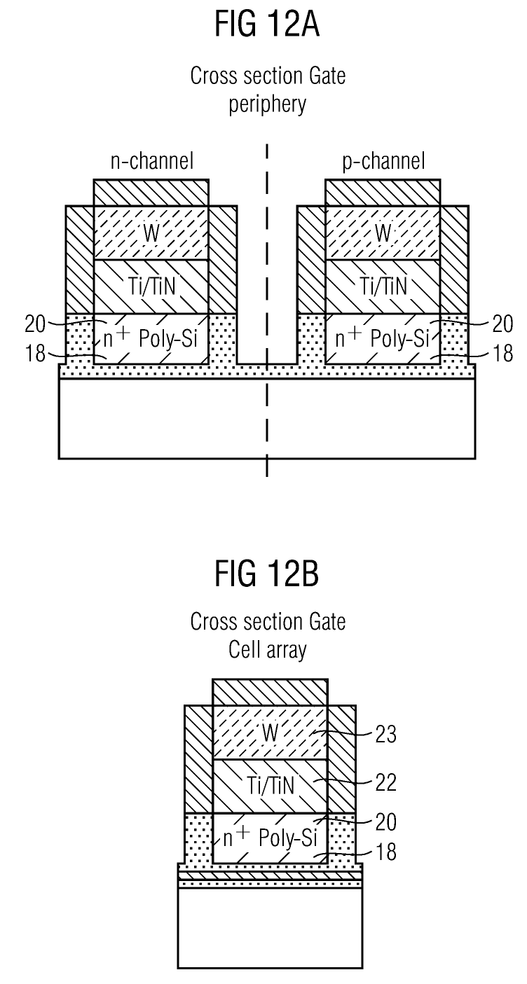

FIGS. 12a and 12b illustrate cross sections of gate regions in the periphery area and in the array area, respectively. These cross sections illustrate the essential components of the SONOS memory device. As it can be seen from those figures, each gate region of the memory device includes a dual layer structure of poly-Si layers, i.e. first poly-Si gate layer 18 and second poly-Si gate layer 20. In the periphery area, there are n-channel transistors and p-channel transistors. The n-channel transistors have their poly-Si gate layers doped with n⁺ ions injected by an implantation method. The p-channel transistors have their poly-Si gate layers doped with p⁺ ions injected by an implantation method.

On the other side, as can be seen from FIG. 12b, in the transistors of the memory cell array area, the first poly-Si layer 18 is doped in high concentration with p⁺ ions that have been induced by plasma doping, and the second poly-Si layer 20 is doped in a lower concentration with p⁺ ions that have been induced by ion implantation.

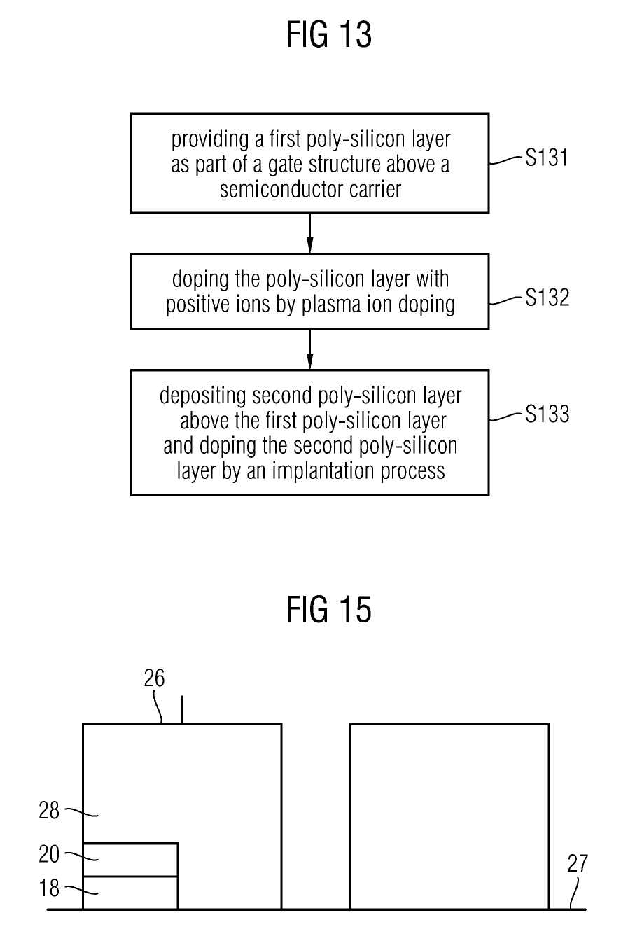

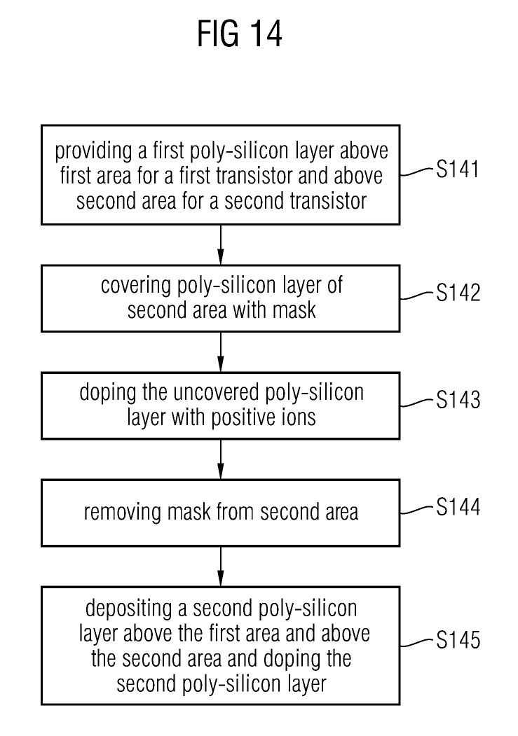

FIGS. 13 and 14 illustrate respective flow charts of a method of manufacturing an integrated circuit.

According to FIG. 13, one embodiment of a method of manufacturing an integrated circuit includes: providing a first polysilicon layer as part of a gate structure above a semiconductor carrier (131); doping the first polysilicon layer with positive ions by a plasma ion doping (132); depositing a second polysilicon layer above the first polysilicon layer and doping the second polysilicon layer by an implantation process (133).

The process illustrated in FIG. 14 is directed to a method of manufacturing an integrated circuit, which method includes: providing a first polysilicon layer above a first area for a gate structure of a first transistor of the integrated circuit to be formed and above a second area for a gate structure of a second transistor of the integrated circuit to be formed (141); covering the polysilicon layer of the second area with a mask (142); doping the uncovered polysilicon layer with positive ions by plasma ion doping (143); removing the mask from the second area (144); and depositing a second polysilicon layer above the first area and above the second area and doping the second polysilicon layer by an implantation process (145).

Also in this case, the doping of the first polysilicon layer may be done by plasma ion doping and the doping of the second polysilicon layer may be done by an implantation process, as it has been described above. With the different doping methods a relative high concentration of dopant in the lower regions of the poly-Si layer of the second area can be achieved and so a migration of ions away from a highly doped layer underneath the lower polysilicon layer to the polysilicon layer due to a doping gradient can be avoided.

In FIG. 15, there is illustrated one embodiment of a system according to the present invention. The system includes a number of integrated circuits 26 which may be designed for fulfilling different purposes. Some of the integrated circuits may contain memory devices, for example SONOS-memory devices. The integrated circuits may be provided on a common wiring plate 27.

As it is depicted in the drawing, one or more of the integrated circuits 26 have a transistor 28 built therein. The transistors 28 include a polysilicon double layer structure which is part of a gate structure. The polysilicon double layer structure includes a first polysilicon layer 18 and a second polysilicon layer 20, wherein the first polysilicon layer is doped with positive ions to a higher concentration than the second polysilicon layer.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing an integrated circuit, the method comprising:
providing a first polysilicon layer as part of a gate structure above a semiconductor carrier;
doping the first polysilicon layer with positive ions by a plasma ion doping; and
depositing a second polysilicon layer above the first polysilicon layer and doping the second polysilicon layer with positive ions by an implantation process.

2. A method according to claim 1, comprising providing a gate contact layer above the second polysilicon layer.

3. The method according to claim 1, comprising wherein a thickness of the second polysilicon layer is higher than a thickness of the first polysilicon layer.

4. The method according to claim 1, comprising using boron ions as the positive ions for doping at least one of the first polysilicon layer and the second polysilicon layer.

5. The method according to claim 1, comprising providing an oxide-nitride-oxide layer as a part of the gate structure.

6. The method according to claim 3, comprising doping the top oxide layer of the oxide-nitride-oxide layer structure and the first polysilicon layer to saturation with boron ions.

7. The method according to claim 1, comprising doping the first polysilicon layer to a boron ion concentration of at least 10¹⁹ to 10²⁰ ions per cm³.

8. The method according to claim 1, comprising doping the second polysilicon layer with a concentration of at least 10¹⁸ to 10¹⁹ ions per cm³.

9. The method according to claim 1, comprising doping the first polysilicon layer to an ion concentration which is at least 10 times as high as the concentration of ions to which the second polysilicon layer is doped.

10. The method according to claim 1, comprising doping a layer of titanium and/or titanium nitride deposited between the upper polysilicon layer and the gate contact.

11. A method of manufacturing an integrated circuit, the method comprising:
providing a first polysilicon layer above a first area for a gate structure of a first transistor of the integrated circuit to be formed and above a second area for a gate structure of a second transistor of the integrated circuit to be formed;
covering the polysilicon layer of the second area with a mask;
doping the uncovered polysilicon layer with positive ions;
removing the mask from the second area; and
depositing a second polysilicon layer above the first area and above the second area and doping the second polysilicon layer.

12. The method according to claim 11, comprising providing a gate contact layer above the second poly silicon layer.

13. The method according to claim 11, comprising wherein providing, prior to the provision of the first poly silicon layer, an oxide-nitride-oxide layer above at least one of the first area for the gate structure of the first transistor of the integrated circuit to be formed and the second area for the gate structure of the second transistor of the integrated circuit to be formed.

14. The method according to claim 13, comprising doping the top oxide layer of the oxide-nitride-oxide layer in the same process as the first poly silicon layer.

15. A system comprising:
integrated circuits, at least one of the integrated circuits having at least one transistor, the transistor comprising a polysilicon double layer with a first polysilicon layer and a second polysilicon layer above the first polysilicon layer, the first polysilicon layer being doped with positive ions to a higher concentration than the second polysilicon layer.

16. A system according to claim 15, comprising wherein at least one of the integrated circuits is a semiconductor memory.

17. A system according to claim 16, comprising wherein the semiconductor memory is a SONOS memory.

18. An integrated circuit comprising:
a gate structure which comprises a polysilicon double layer, the polysilicon double layer comprising a first polysilicon layer and a second polysilicon layer formed above the first polysilicon layer, the first polysilicon layer being doped with positive ions to a higher concentration than the second polysilicon layer.

19. The integrated circuit according to claim 18, comprising wherein a thickness of the second polysilicon layer is higher than a thickness of the first polysilicon layer.

20. The integrated circuit according to claim 18, comprising wherein the positive ions are boron ions.

21. The integrated circuit according to claim 18, comprising wherein an oxide-nitride-oxide structure is provided as a part of the gate structure and the top oxide layer of the oxide-nitride-oxide layer structure as well as the polysilicon layer are saturated with boron ions.

22. The integrated circuit according to claim 18, comprising wherein the first polysilicon layer has a substantially constant concentration of ions across its thickness, whereas the concentration of ions in the second polysilicon layer is higher on a side opposite of the first polysilicon layer than in a region at a boundary with the first polysilicon layer.

23. The integrated circuit according to claim 18, comprising wherein the ion concentration of the first polysilicon layer is at least 10 times higher than the ion concentration in the second polysilicon layer.

24. An integrated circuit comprising:
a gate structure which comprises a polysilicon double layer, the polysilicon double layer comprising:
means for providing a first polysilicon layer; and
means for providing a second polysilicon layer formed above the first polysilicon layer means, the first polysilicon layer means being doped with positive ions to a higher concentration than the second polysilicon layer means.
